(19) United States
(12) Patent Application Publication
(10) Pub. No.: US 2023/0282644 A1
(43) Pub. Date: Sep. 7, 2023

(54) LAYOUT DESIGN FOR RF CIRCUIT

(71) Applicant: Taiwan Semiconductor Manufacturing Company, Ltd., Hsinchu (TW)

(72) Inventors: Ho-Hsiang CHEN, Hsinchu City (TW); Chi-Hsien LIN, Taichung City (TW); Ying-Ta LU, Hsinchu City (TW); Hsien-Yuan LIAO, Hsinchu City (TW); Hsiu-Wen WU, Taoyuan City (TW); Chiao-Han LEE, Taichung City (TW); Tzu-Jin YEH, Hsinchu City (TW)

(73) Assignee: Taiwan Semiconductor Manufacturing Company, Ltd., Hsinchu (TW)

(21) Appl. No.: 17/854,646

(22) Filed: Jun. 30, 2022

Related U.S. Application Data
(60) Provisional application No. 63/316,037, filed on Mar. 3, 2022.

(51) Int. Cl. H01L 27/118; H03F 1/26; H01L 23/522; H03F 1/22; H01L 23/528

(52) U.S. Cl. CPC H01L 27/11807; H03F 1/26; H01L 23/5226; H03F 1/223; H01L 23/528; H01L 2027/11875; H03F 2200/294; H03F 2200/451

(57) ABSTRACT

A cell layout design for an integrated circuit. In one embodiment, the integrated circuit includes a dual-gate cell forming two transistors connected with each other via a common source/drain terminal. The dual-gate cell includes an active region, two gate lines extending across the active region, at least one first gate via disposed on one or both of the two gate lines and overlapped with the active region, and second gate vias disposed on one or both of the two gate lines and located outside the active region.

### CROSS-REFERENCE TO RELATED APPLICATIONS

This application claims the benefit of U.S. Provisional Application No. 63/316,037, filed Mar. 3, 2022, and titled “LAYOUT DESIGN FOR RF CIRCUIT,” the disclosure of which is hereby incorporated herein by reference.

### BACKGROUND

RF circuits, such as that used for a transceiver front-end circuitry, is made up of building blocks including low noise amplifier (LNAs), voltage-controlled oscillators (VCOs), and RF mixers. Due to smaller metal wires and vias being used in such devices, parasitic capacitance and resistance tend to increase. For middle-end-of-line (MEOL) layers which adopt double-patterning technology, this trend limits the freedom of circuit layouts. For example, pitch in the horizontal direction of a circuit layout is limited by the critical gate pitch, and pitch in the vertical direction is limited by the fin pitch and/or nanosheet width.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a cell layout having a first type of dual-gate design in accordance with some embodiments.

FIG. 1B is a schematic of a cascoded transistor configuration formed by the first type of dual-gate design in accordance with some embodiments.

FIG. 1C is a circuit diagram of a low noise amplifier circuit including the cascoded transistor configuration of the first type of dual-gate design in accordance with some embodiments.

FIG. 1D illustrates a cell layout showing MEOL layer connections for the cascoded transistor configuration of the first type of dual-gate design in accordance with some embodiments.

FIG. 2A is a cell layout having a second type of dual-gate design in accordance with some embodiments.

FIG. 2B is a schematic of a stacked gate transistor configuration formed by the second type of dual-gate design in accordance with some embodiments.

FIG. 2C is a circuit diagram of a voltage-controlled oscillator circuit including the stacked gate transistor configuration of the second type of dual-gate design in accordance with some embodiments.

FIG. 2D illustrates a cell layout showing MEOL layer connections for the dual-gate stacked cell in accordance with some embodiments.

FIG. 2E illustrates a cell layout showing MEOL layer connections for the quad gate stacked cell in accordance with some embodiments.

FIG. 2F illustrates the cell layout showing gate connections for the quad gate stacked cell in accordance with some embodiments.

FIG. 3 is a table summarizing the measured characteristics of various gate contact arrangements for cell layouts in accordance with some embodiments.

FIG. 4A is a circuit diagram of an octa gate circuit including the stacked gate transistor configuration of the second type of dual-gate design in accordance with some embodiments.

FIG. 4B illustrates a cell layout showing MEOL layer connections for the octa gate circuit in accordance with some embodiments.

FIG. 4C is a circuit diagram of a quadrature voltage-controlled oscillator circuit based on the octa gate circuit in accordance with some embodiments.

FIG. 4D illustrates a cell layout showing MEOL layer connections for two octa gate circuits and in accordance with some embodiments.

FIG. 4E illustrates a cell layout showing MEOL layer connections for the quad gate circuit in accordance with some embodiments.

FIG. 5A is a circuit diagram of an RF mixer circuit based on the octa gate circuit in accordance with some embodiments.

FIG. 5B illustrates a cell layout showing MEOL layer connections for the octa gate circuit of the RF mixer circuit in accordance with some embodiments.

FIG. 5C illustrates a cell layout showing MEOL layer connections for the quad gate circuit of the RF mixer circuit in accordance with some embodiments.

FIG. 6A is a circuit diagram of a hexadeca gate circuit based on the octa gate circuit in accordance with some embodiments.

FIG. 6B illustrates a cell layout showing MEOL layer connections for the hexadeca gate circuit in accordance with some embodiments.

FIG. 7 is a circuit diagram of a Quadrature Gilbert cell circuit based on the hexadeca gate circuit in accordance with some embodiments.

FIG. 8A is a circuit diagram of an octa gate circuit including the cascoded transistor configuration of the first type of dual-gate design in accordance with some embodiments.

FIG. 8B illustrates a cell layout showing MEOL layer connections for the octa gate circuit in accordance with some embodiments.

FIG. 8C is a circuit diagram of an RF mixer circuit based on the octa gate circuit in accordance with some embodiments.

FIG. 9A illustrates a cell layout with a cut first metallization layer in accordance with some embodiments.

FIG. 9B is a schematic diagram of the first metallization layer M0 with perpendicular cut-metal layer in accordance with some embodiments.

FIG. 9C is a table summarizing characteristics of the cell layout having the cut first metallization layer M0 in accordance with some embodiments.

FIG. 10 illustrates an example method of forming a cell in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Some disclosed embodiments herein relate to a cell layout for RF circuits. As the integrated circuit industry has progressed into multiple technology nodes of 7 nm (N7), 5 nm (N5), 3 nm (N3), and beyond, there is less space between via contacts and also between metal lines. According to the embodiments of the disclosure, the gate contact arrangements described herein allow combining two or more transistors in a cell in a periodic layout that can be scaled for RF circuits to reduce parasitic resistance and capacitance. In a conventional layout for transistors in a low noise amplifier, the common source and common gate are separate by different active regions. In another conventional layout for transistors in a low noise amplifier, the common source and common gate are both deployed with gate contacts outside the active region. However, these conventional gate contact arrangements cannot be scaled to improve RF circuitry performance.

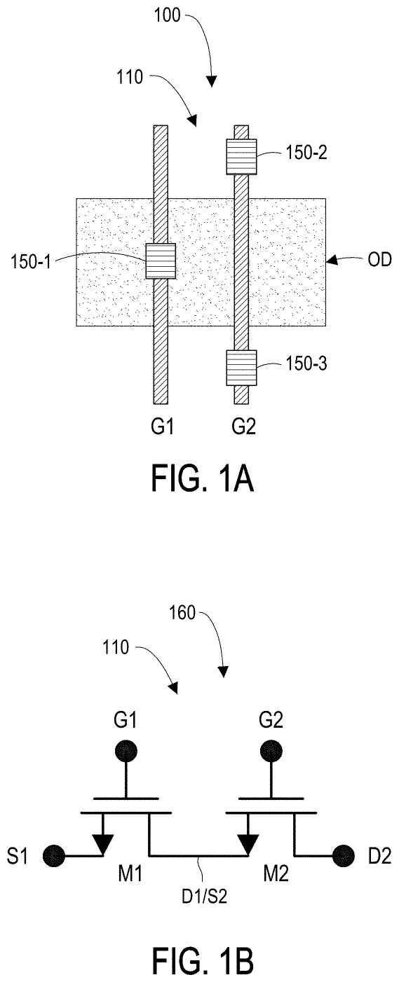

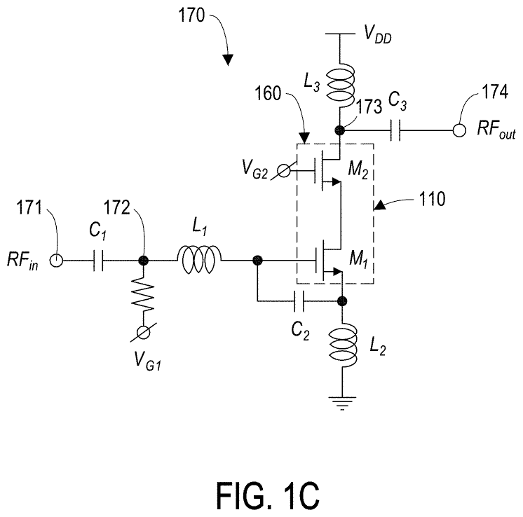

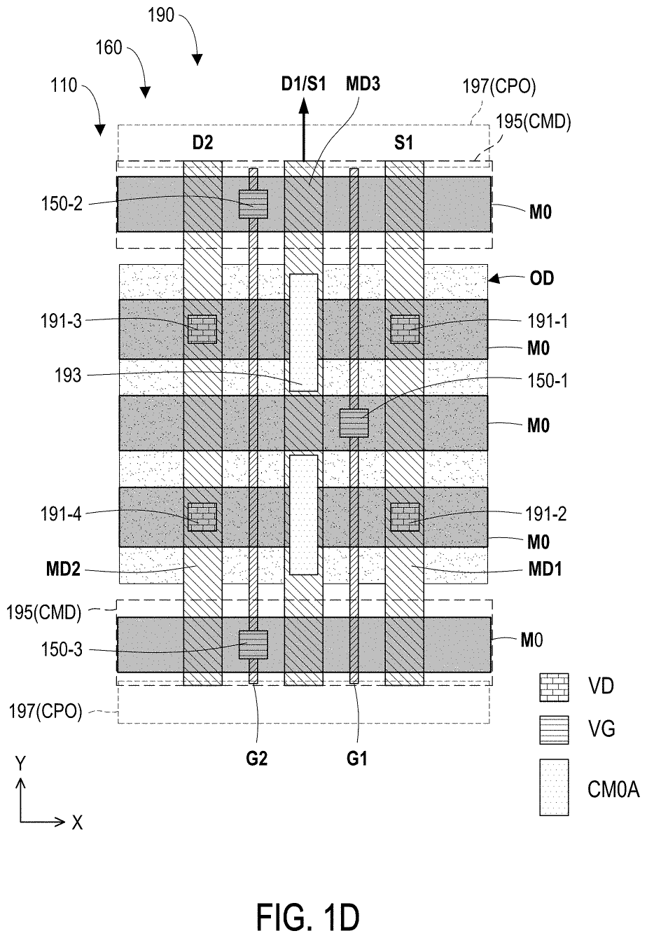

FIG. 1A is a cell layout 100 having a first type of dual-gate design 110 in accordance with some embodiments. The term “cell” used throughout the present disclosure refers to a group of circuit patterns in a design layout to implement specific functionalities of a circuit. For example, a cell may be designed to implement an electronic circuit formed by one or more semiconductor devices (e.g., a metal-oxide-semiconductor field-effect transistor (MOSFET) device, a fin-type FET (FinFET) device, or the like). A cell is generally comprised of one or more layers, and each layer includes various patterns expressed as polygons of the same or various shapes.

In FIG. 1A, cell layout 100 includes multiple layers overlaid with one another along with various patterns in the respective layers from a top-view perspective. In particular, cell layout 100 include an active region OD which is, for example, an oxide-defined region in which a transistor may be formed. For example, active region OD may be configured for forming channels of transistors and made of an n-type or p-type doped material. Cell layout 100 also includes gates G1 and G2 disposed across the active region OD. Gates G1 and G2 may sometimes be referred to as gate lines, gate structures, gate regions, or gate electrodes. In some embodiments, gates G1 and G2 are poly silicon gates having a pattern designated as PO and may be schematically labelled as such in the figures. Other conductive materials for conductive gates, such as metals, are within the scope of various embodiments.

In the first type of dual-gate design 110 of FIG. 1A, gates G1 and G2 and active region OD form two transistors. Although not shown in FIG. 1A, it is understood that each gate G1 and G2 is formed over the active region OD with corresponding source/drain structures/regions to function as a respective transistor. The source/drain structures can conduct current through the active region OD, which is gated (e.g., modulated) by a respective gate G1/G2. For example, each gate G1/G2 may be formed over (e.g., to straddle) the active region OD of an n-type MOSFET (NMOS) to modulate current conducting through the transistor. Such functional structures of a transistor are collectively referred to as front-end-of-line (FEOL) structures. Gates G1 and G2 may be embedded in a dielectric layer, typically referred to as an inter-layer dielectric (ILD) layer, which may comprise a low-k dielectric material.

Gates G1 and G2 electrically couple to one or more metallization layers formed over the dielectric layer using one or more via over gates (VGs) 150, sometimes referred to as via structures or gate vias. As used herein, the term via includes its use as an acronym for “vertical interconnect access.” The layer formed immediately above the gate structures is sometimes referred to as an M0 layer. The structures formed in and above the M0 layer (e.g., M1 layer, M2 layer, etc.) may be collectively referred to as back-end-of-line (BEOL) structures. Middle-of-line (MEOL) structures may therefore refer to contacts that physically and/or electrically connect a FEOL structure to a BEOL structure, such as VGs 150 that connect gates G1 and G2 to the first metallization layer M0.

Additionally, although not shown in FIG. 1A for simplicity, it is understood that isolation features formed in the substrate of an integrated circuit (IC) define different active regions including active region OD. That is, the isolation features electrically isolate transistors or devices formed in and/or over the substrate in different regions. In some embodiments, the isolation features include shallow trench isolation (STI) features. Accordingly, an area or region outside active region OD may be designated STI and/or schematically labelled as such in the figures. Other features for isolating active regions, such as local oxidation of silicon (LOCOS) features and/or various combinations of other suitable isolation features, are within the scope of various embodiments.

In the first type of dual-gate design 110 of FIG. 1A, first gate G1 includes a first VG 150-1 that is overlapped with the active region OD, and second gate G2 includes second VGs 150-2 and 150-3 located outside the active region OD (e.g., STI region). The arrangement of VGs 150 of cell layout 100 enables two transistors of the same cell to connect in a cascoded configuration with a common source/drain terminal. Moreover, as described in greater detail below, the first type of dual-gate design 110 may be implemented in RF circuitry such as low noise amplifiers to improve RF circuitry performance.

FIG. 1B is a schematic of a cascoded transistor configuration 160 formed by the first type of dual-gate design 110 in accordance with some embodiments. In the cascoded transistor configuration 160, the first transistor M1 and the second transistor M2 are electrically coupled to each other in series. In particular, a drain D1 of the first transistor M1 is connected to a source S2 of the second transistor M2. Transistors M1 and M2 are thus connected via a common source/drain terminal (e.g., D1/S2). Moreover, gates G1 and G2 include or connect with respective VGs 150 as described above with respect to FIG. 1A. The first transistor M1 and second transistor M2 may comprise NMOS transistors.

FIG. 1C is a circuit diagram of a low noise amplifier circuit 170 including the cascoded transistor configuration 160 of the first type of dual-gate design 110 in accordance with some embodiments. The low noise amplifier circuit 170 may be implemented, for example, in the first circuit block of the receiver of a wireless RF device. Low noise amplifiers are typically designed with a low noise figure (NF) so as to amplify low power signals while minimizing additional noise. As described in greater detail below, the cascoded transistor configuration 160 of the first type of dual-gate design 110 is advantageously configured to optimize gain and noise figure in the low noise amplifier circuit 170.

The low noise amplifier circuit 170 includes a cascode gain stage according the cascoded transistor configuration 160 described above with respect to FIG. 1B. The second transistor M2 may comprise a common gate transistor with a gate connected to a biasing voltage V_{G2}. The source S2 of the second transistor M2 is connected to the drain D1 of the first transistor M1 which may comprise a common source transistor. The gate of the first transistor M1 is coupled to an input node 171 for receiving an RF input signal through a first capacitor C₁ and a first inductor L₁. A second node 172 between the first capacitor C₁ and the first inductor L₁ couples to a voltage source node VG1 (e.g., through a resistor) for biasing the gate voltage of the first transistor M1. The gate and source of the first transistor M1 may be coupled through a second capacitor C₂, and the source may also be coupled to ground through a second inductor L₂. The drain of the second transistor M2 may be coupled to a power supply V_{DD} through a third inductor L₂. A third node 173 coupled to the drain of the second transistor M2 may be connected to an output node 174 through a third capacitor C₃. The output node 174 may provide an RF output signal for the low noise amplifier circuit 170.

FIG. 1D illustrates a cell layout 190 showing MEOL layer connections for the cascoded transistor configuration 160 of the first type of dual-gate design 110 in accordance with some embodiments. As earlier described with respect to FIG. 1A, both gates G1 and G2 are disposed on the same active region OD. The first gate G1 includes the first VG 150-1 which is disposed directly above the active region OD (e.g., centered over the active region OD with respect to Y-direction). The second gate G2 includes second VGs 150-2 and 150-3 disposed over the STI region beyond opposite sides of the active region OD. That is, one second VG 150-2 is disposed outside a top edge of the active region OD and another second VG 150-2 is disposed outside a bottom edge of the active region OD.

The cell layout 190 also shows a metal-to-diffusion (MD) layer which may extend over the active region OD to connect to source/drain structures of the first transistor M1 and second transistor M2. In particular, a first MD track MD1 connects to the source S1 of the first transistor M1, a second MD track MD2 connects to the drain D2 of the second transistor M2, and a third MD track MD3 connects to the common source/drain terminal D1/S2. The MD tracks MD1-3 extend in a Y-direction parallel with the gates G1 and G2. The third MD track MD3 is disposed between the gates G1 and G2 in the X-direction, and the second MD track MD2 and first MD track MD1 are disposed outside the gates G1 and G2, respectively, in the X-direction.

Above the MD layer along a vertical or Z-direction, a via over diffusion (VD) layer including via contacts 191 can be formed. Like VGs 150 earlier described, the VD layer may be disposed between and couple the MD layer to the first metallization layer M0. In particular, first MD track MD1 includes or connects with a first via contact 191-1 and second via contact 191-2, and second MD track MD2 includes or connects with a third via contact 191-3 and a fourth via contact 191-4. The via contacts 191 may each be disposed to overlap with the active region OD. The first metallization layer M0 may be cut to include a cut M0 color A (CM0A) level disposed along the third MD layer interconnect MD3. Extra source and drain extensions on the STI region may be cut by a cut MD (CMD) region 195 at top and bottom sides of the active region OD. Still further, a cut poly region (CPO) 197 may be disposed along the top and bottom cell edge.

Accordingly, in the cell layout 190 including the first type of dual-gate design 110, a single VG (e.g., first VG 150-1) is disposed on the first gate G1 and overlapped with the active region OD, and the first transistor M1 may comprise a first stage of the cascoded transistor configuration 160 to optimize for higher gain. Moreover, two VGs (e.g., second VGs 150-2 and 150-3) are disposed on the second gate G2 and located outside the active region OD, and the second transistor M2 may comprise a second stage of the cascoded transistor configuration 160 to optimize for lower noise figure. Additionally, the cell layout 190 including the first type of dual-gate design 110 achieves a compact size which adopts a CM0 approach with abutting cells to form a highly periodic array of identical cells useful for scaling an RF circuit while reducing parasitic resistance and capacitance.

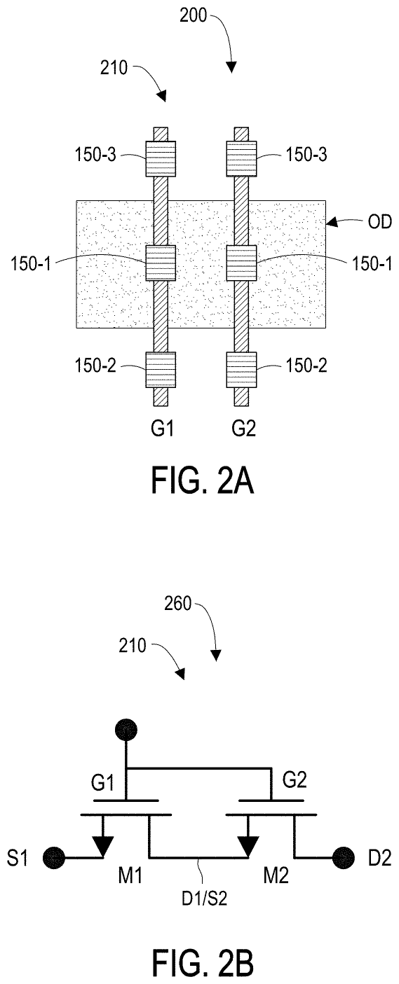

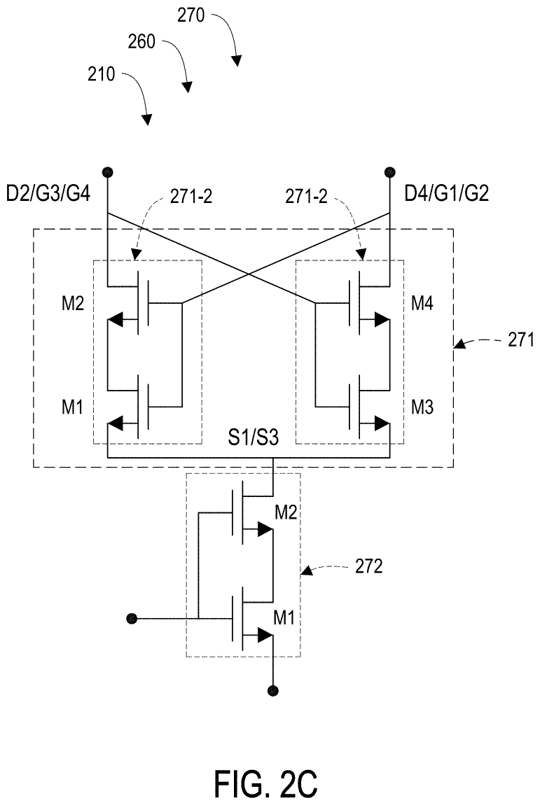

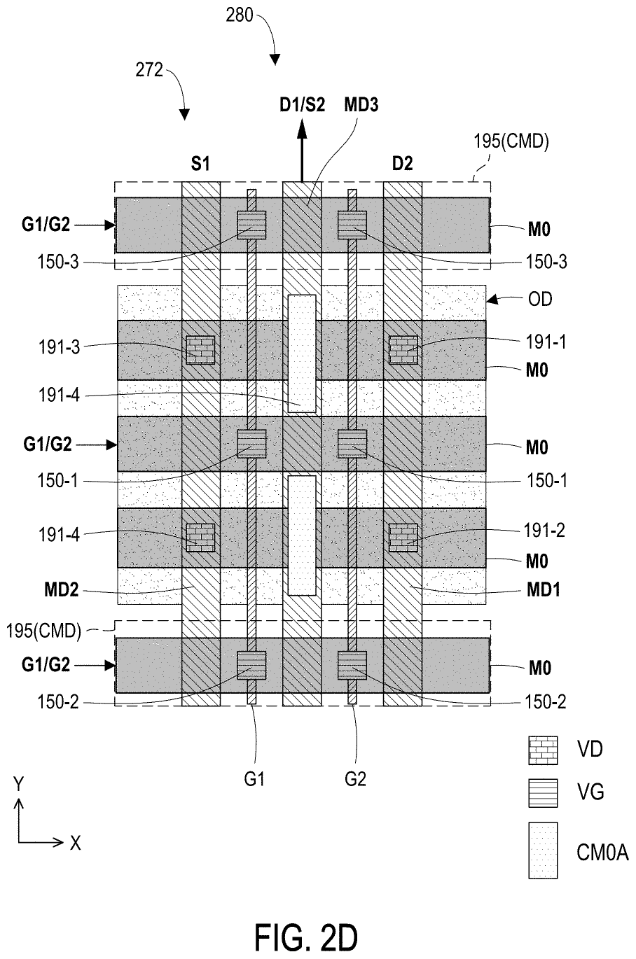

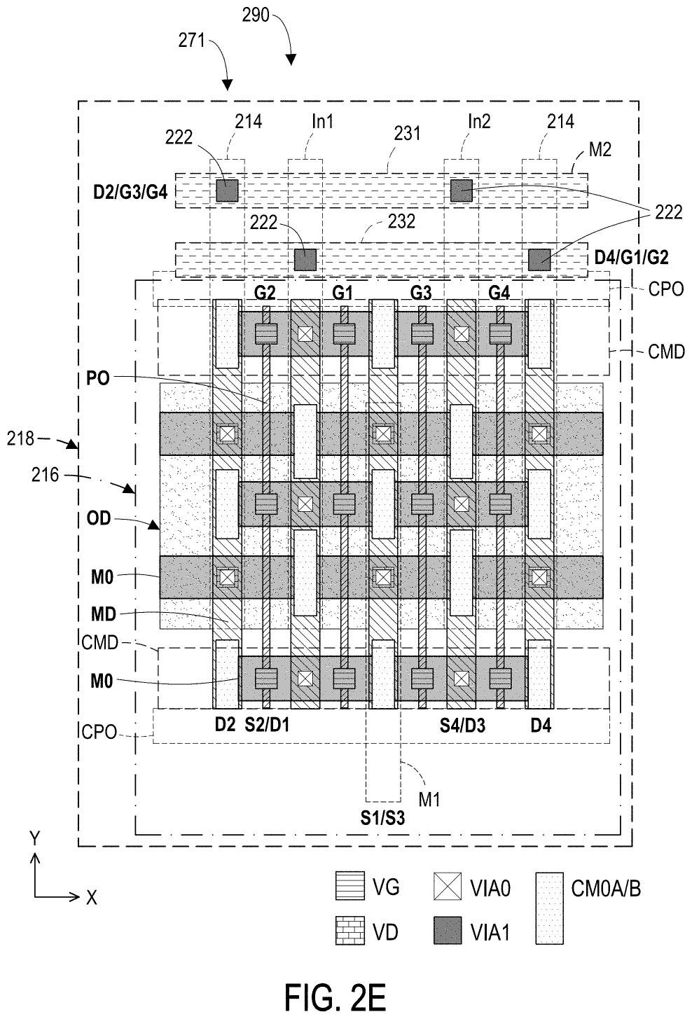

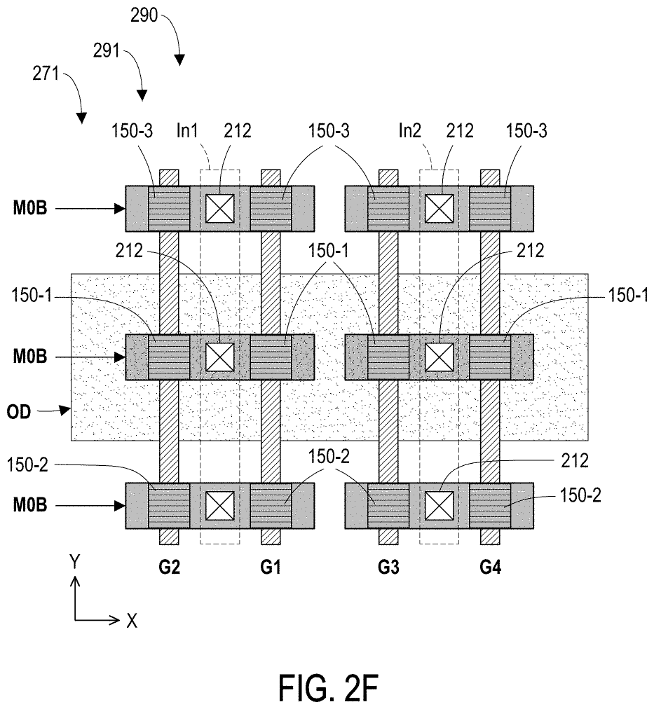

FIG. 2A is a cell layout 200 having a second type of dual-gate design 210 in accordance with some embodiments. In the second type of dual-gate design 210, gates G1 and G2 are disposed over the same active region OD and each of the first gate G1 and the second gate G2 are routed by three VGs. In particular, the first gate G1 includes a first VG 150-1 overlapped with the active region OD, and a second VG 150-2 and third VG 150-3 disposed over the STI region beyond opposite sides of the active region OD. Similarly, the second gate G2 includes a first VG 150-1 overlapped with the active region OD, and a second VG 150-2 and third VG 150-3 disposed over the STI region beyond opposite sides of the active region OD.

FIG. 2B is a schematic of a stacked gate transistor configuration 260 formed by the second type of dual-gate design 210 in accordance with some embodiments. Similar to that described above with respect to the first type of dual-gate design 110, the first transistor M1 and the second transistor M2 are connected via a common source/drain terminal (e.g., D1/S2) in the second type of dual-gate design 210. However, in the second type of dual-gate design 210, the first transistor M1 and the second transistor M2 include respective gates G1 and G2 coupled together. Moreover, Gates G1 and G2 include a cell arrangement with respective VGs 150 as described above with respect to FIG. 2A.

FIG. 2C is a circuit diagram of a voltage controlled oscillator circuit 270 including the stacked gate transistor configuration 260 of the second type of dual-gate design 210 in accordance with some embodiments. In particular, the voltage controlled oscillator circuit 270 comprises a quad gate stacked cell 271 and a dual-gate stacked cell 272. The dual-gate stacked cell 272 includes a first transistor M1 and a second transistor M2 in the stacked gate transistor configuration 260 described above with respect to FIG. 2B. The drain D2 of the second transistor M2 connects to the sources S1/S3 of the first transistor M1 and third transistor M2 of the quad gate stacked cell 271. The quad gate stacked cell 271 includes a first transistor pair 271-1 and a second transistor pair 271-2 that are cross-coupled to form the quad gate stacked cell 271. Connections of the dual-gate stacked cell 272 and the quad gate stacked cell 271 are further described below in FIGS. 2D and 2E-F, respectively.

FIG. 2D illustrates a cell layout 280 showing MEOL layer connections for the dual-gate stacked cell 272 in accordance with some embodiments. FIG. 2E illustrates a cell layout 290 showing MEOL layer connections for the quad gate stacked cell 271 in accordance with some embodiments. FIG. 2F illustrates the cell layout 290 showing gate connections 291 for the quad gate stacked cell 271 in accordance with some embodiments. As earlier described, the dual-gate stacked cell 272 and the quad gate stacked cell 271 implement the stacked gate transistor configuration 260 of the second type of dual-gate design 210 previously described with respect to FIGS. 2A-2B.

Referring now to FIG. 2D, both gates G1 and G2 are disposed on the same active region OD. Each of the first gate G1 and the second gate G2 include respective first VGs 150-1 disposed directly above the active region OD (e.g., centered over active region OD with respect to Y-direction). Additionally, each of the first gate G1 and the second gate G2 include respective second VGs 150-2 and third VGs 150-3 located outside the active region OD at opposite sides thereof. Accordingly, the gates G1 and G2 are coupled to the first metallization layer M0 tracks as shown by arrows in FIG. 2D. The cell layout 280 may include a similar configuration of the MD layer, VD layer/contacts, source/drain connections, etc. as that described with respect to FIG. 1D and a description of such is thus omitted for brevity.

In the cell layout 290 shown in FIGS. 2E-2F, there are four transistors in a cell and gates G1-G4 extend across the active region OD. As shown in FIG. 2F, the first transistor M1 and the third transistor M3 have common/connected sources S1/S3 which may be formed to extend in the Y-direction and at center with respect to X-direction of the cell layout 290. The first transistor M1 and the second transistor M2 are disposed to a left of the common sources S1/S3, and the third transistor M3 and the fourth transistor M4 are disposed to a right of the common sources S1/S3 to form the stacked gate transistor configuration 260.

As perhaps best shown in FIG. 2F, gates G1 and G2 are common and form a first differential input (In1) for the voltage controlled oscillator circuit 270 by connection to a second metallization layer M1 or track indicated by the dashed line. That is, via connections 212 (e.g., VIA0) route the connection from the first metallization layer M0 or track (e.g., MOB which connects gates G1 and G2 with VGs 150) to the second metallization layer M1. Similarly, gates G3 and G4 are common and form a second differential input (In2) for the voltage controlled oscillator circuit 270 by connection to the second metallization layer M1 in a similar manner.

Additionally, referring again to FIG. 2E, drains D2 and D4 form differential outputs 214 at the two outer sides of the cell for the voltage controlled oscillator circuit 270 by connection to the second metallization layer M1. Outlined region 216 shows the MEOL layer connections for the quad gate differential pair of the voltage controlled oscillator circuit 270. Moreover, outlined region 218 shows the MEOL layer connections for the quad gate cross-coupled pair of the voltage controlled oscillator circuit 270. Via connections 222 (e.g., VIA1) route connections to a third metallization layer M2 for the quad gate cross-coupled pair. In particular, the third gate G3 and fourth gate G4 are common with the second drain D2 to form a first differential output 231 by the third metallization layer M2. Similarly, the first gate G1 and the second gate G2 are common with the fourth drain D4 to form a second differential output 232 by the third metallization layer M2.

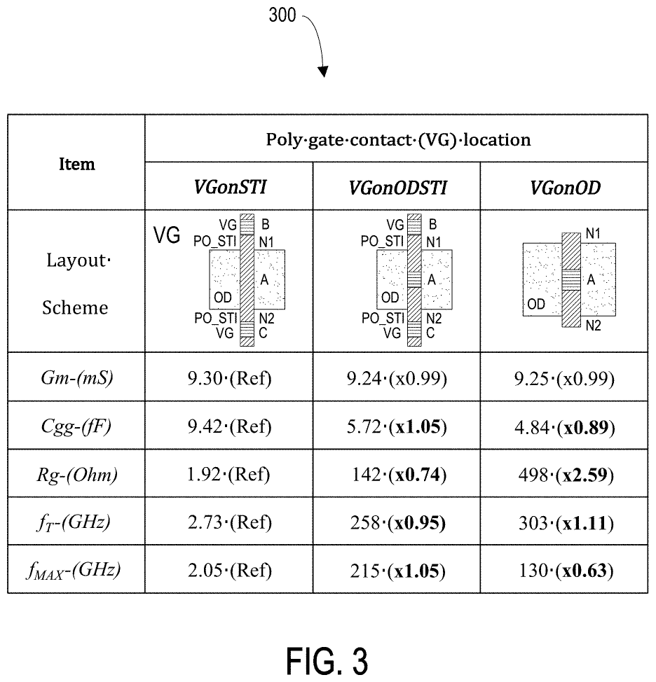

FIG. 3 is a table 300 summarizing the measured characteristics of various gate contact arrangements for cell layouts in accordance with some embodiments. The first type of dual-gate design 110 discussed with respect to FIGS. 1A-D relates to a configuration in which the first gate G1 has a VG overlapped with the active region OD (e.g., referred to as “VGonOD” in table 300), and the second gate G2 has two VGs outside the active region OD (e.g., referred to as “VGonSTI”). As shown by the table 300, the VGonOD configuration is associated with a high cut-off frequency (e.g., f_{T}=303 GHz) and low total gate capacitance (e.g., C_{gg}=4.84 fF). Since these characteristics are useful for boosting gain, the VGonOD configuration advantageously optimizes gain when used in a first stage of the cascoded transistor configuration 160, as discussed with respect to FIG. 1D. Additionally, the VGonSTI configuration is associated with a relatively low gate resistance (e.g., R_{g}=192 Ohms) and relatively high maximum oscillation frequency (fₘₐₓ=205 GHz). Since these characteristics are useful for reducing noise figure, the VGonSTI configuration advantageously optimizes noise figure when used in a second stage of the cascoded transistor configuration 160.

The second type of dual-gate design 210 discussed with respect to FIGS. 2A-F relates to a configuration in which both the first gate G1 and second gate G2 include one VG overlapped with the active region OD and two VGs outside the active region OD (e.g., referred to as “VGonODSTI” in table 300). As shown by the table 300, the VGonODSTI configuration is associated with a low gate resistance (e.g., R_{g}=142 Ohms). Since this characteristics is useful for reducing thermal noise (e.g., high frequency noise), the VGonODSTI configuration advantageously improves circuit performance when used in the stacked gate transistor configuration 260 for the voltage controlled oscillator circuit 270. Moreover, the quad gate stacked cell 271 and current source (e.g., dual-gate stacked cell 272) are configured to reduce flicker noise (e.g., low frequency noise) to further improve the operation of the voltage controlled oscillator circuit 270.

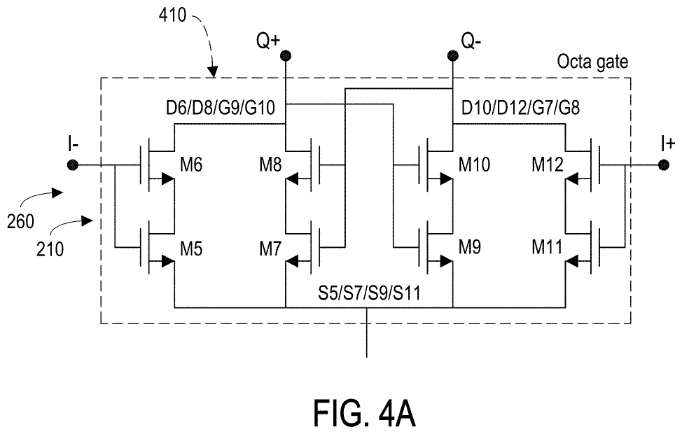

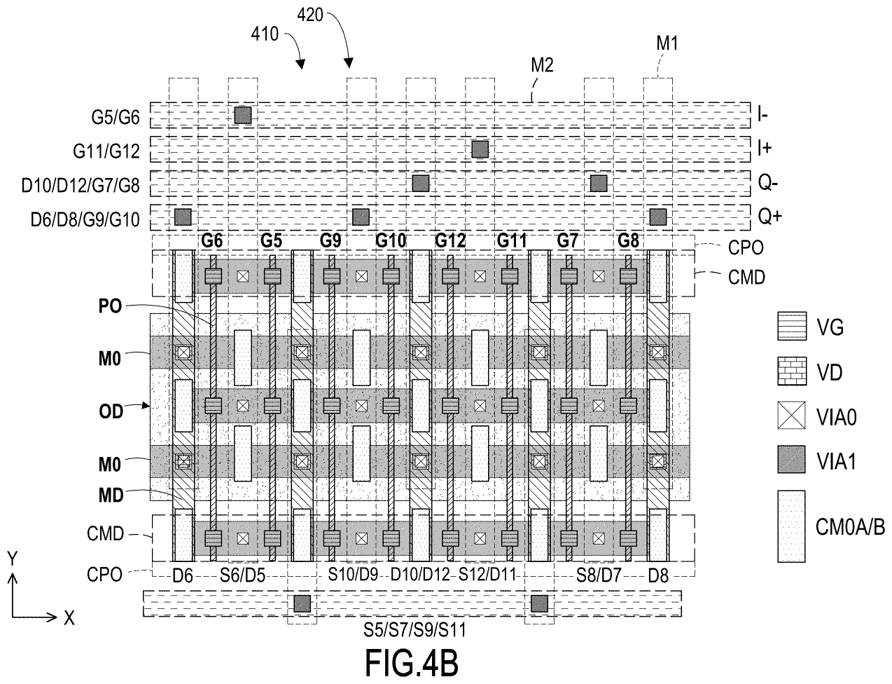

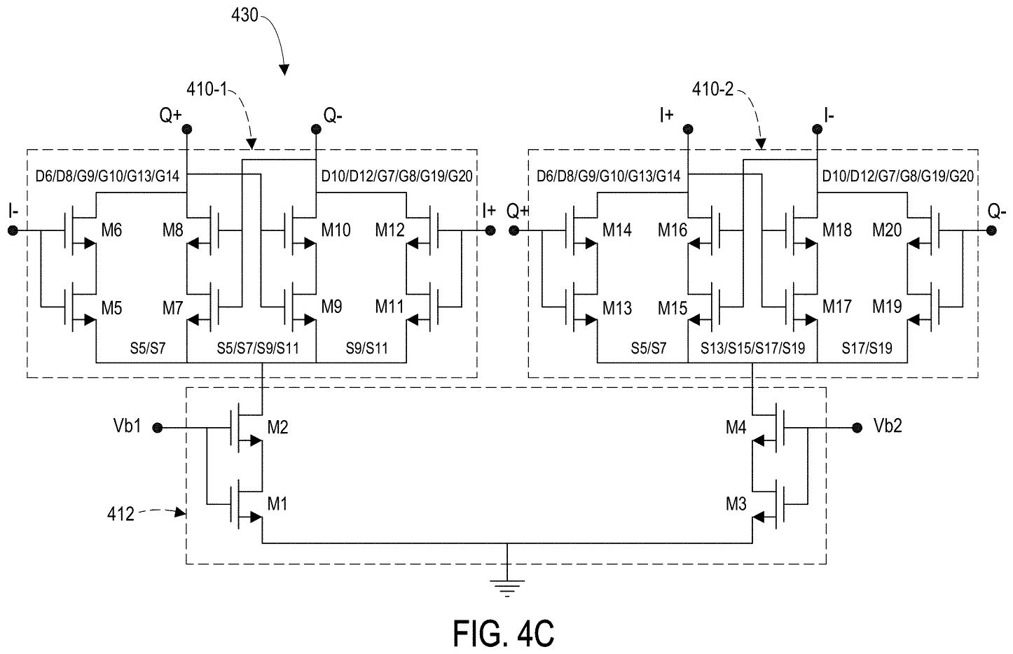

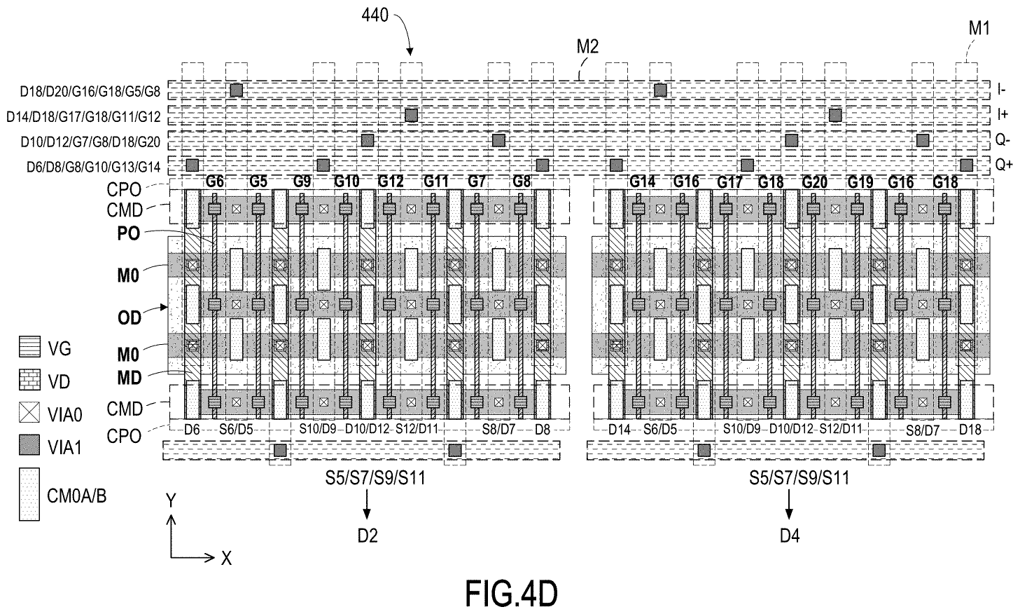

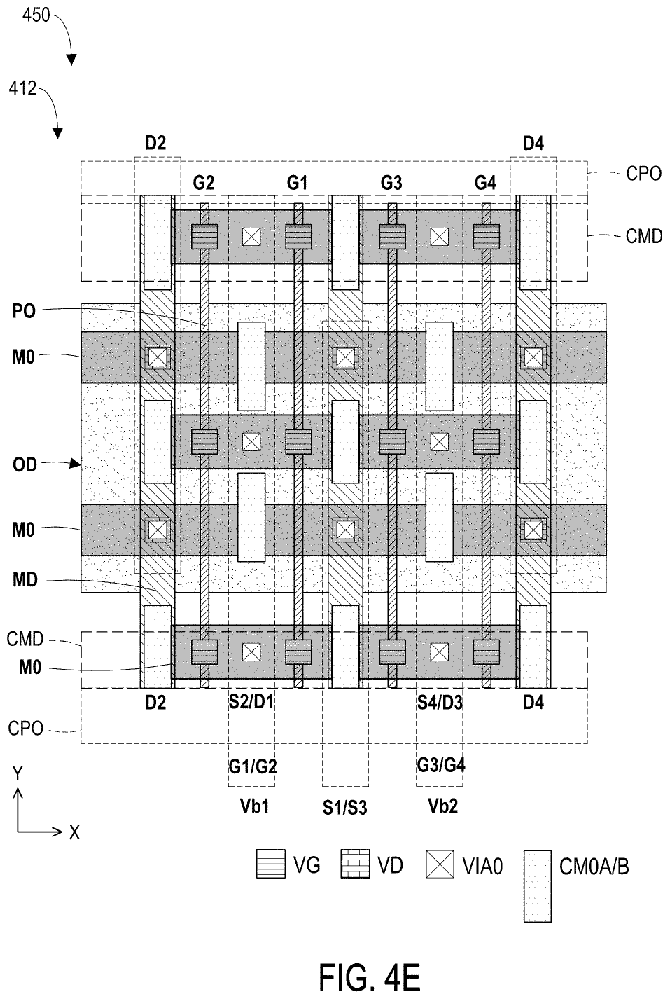

FIG. 4A is a circuit diagram of an octa gate circuit 410 including the stacked gate transistor configuration 260 of the second type of dual-gate design 210 in accordance with some embodiments. The octa gate circuit 410 may include functionality for a voltage controlled oscillator to generate quadrature signals I+(zero degrees), Q+(ninety degrees), I− (one hundred and eighty degrees), and Q− (two hundred and seventy degrees). The octa gate circuit 410 includes eight transistors M5-M12. Gates G5 and G6 are common and coupled to quadrature signal node I+, and gates G11 and G12 are common and coupled to quadrature signal node I−. Moreover, gates G7 and G8 and drains D10 and D12 are coupled to quadrature signal node Q−, and gates G9 and G10 and drains D6 and D8 are coupled to quadrature signal node Q+. Additionally sources S5, S7, S9, and S11 are coupled together.

FIG. 4B illustrates a cell layout 420 showing MEOL layer connections for the octa gate circuit 410 in accordance with some embodiments. In particular, the eight transistors M5-M12 are formed across the active region OD. Common drains D10 and D12 are disposed at center and drains D6 and D8 are disposed at outer sides and connected by the third metallization layer M2. Gates G9 and G10 are dispose to a left of center, and gates G5 and G6 are disposed to the left side of the cell. Gates G11 and G12 are disposed to a right of center, and gates G7 and G8 are disposed to the right side of the cell. Sources S5, S9, S7, and S11 are common and connected to the third metallization layer M2 with a VIA1 disposed between gates G5 and G9 and a VIA1 disposed between gates G7 and G11.

FIG. 4C is a circuit diagram of a quadrature voltage-controlled oscillator circuit 430 based on the octa gate circuit 410 in accordance with some embodiments. In particular, a first octa gate circuit 410-1 and second octa gate circuit 410-2 are combined to form a quadrature cross-coupled pair for the quadrature voltage-controlled oscillator circuit 430. The first octa gate circuit 410-1 includes the eight transistors M5-M12 and connections described above with respect to FIGS. 4A-B. The second octa gate circuit 410-2 is similarly configured with eight transistors M13-M20. Gates G13 and G14 are common and coupled to quadrature signal node Q+, and gates G19 and G20 are common and coupled to quadrature signal node Q−. Moreover, gates G15 and G16 and drains D18 and D20 are coupled to quadrature signal node I−, and gates G17 and G18 and drains D14 and D16 are coupled to quadrature signal node I+. Additionally sources S13, S15, S17, and S19 are coupled together.

The quadrature voltage-controlled oscillator circuit 430 also includes a quad gate circuit 412 including four transistors M1-M4. The first transistors M1 and second transistors M2 are connected in series between the first octa gate circuit 410-1 and ground. Gates G1 and G2 are common and coupled to node Vb1. The drain D2 is coupled to the common sources of the first octa gate circuit 410-1, the source S1 is coupled to ground, and the drain D1 and source S2 are coupled together to form the stacked gate transistor configuration 260. The third transistor M3 and fourth transistor M4 are similarly configured with respect to the first octa gate circuit 410-2 and node Vb2.

FIG. 4D illustrates a cell layout 440 showing MEOL layer connections for two octa gate circuits 410-1 and 410-2 in accordance with some embodiments. As discussed above with respect to FIG. 4C, the two octa gate circuits 410-1 and 410-2 form a quadrature cross-coupled pair for a quadrature voltage-controlled oscillator to generate quadrature phases. The connections are similar to that of the octa gate circuit 410 described above with respect to FIGS. 4A-B and the description of such is thus omitted for brevity.

FIG. 4E illustrates a cell layout 450 showing MEOL layer connections for the quad gate circuit 412 in accordance with some embodiments. The cell layout 450 is similar to the layout of the quad gate stacked cell 271 described above with respect to FIGS. 2D-F and some of the description of such is therefore omitted for brevity. As shown in FIG. 4E, the drain D1 and source S2 may couple with the node Vb1 with a VIA0 to the second metallization layer M1. Similarly, the drains D3 and source S4 may couple with the node Vb2 with a VIA0 to the second metallization layer M1.

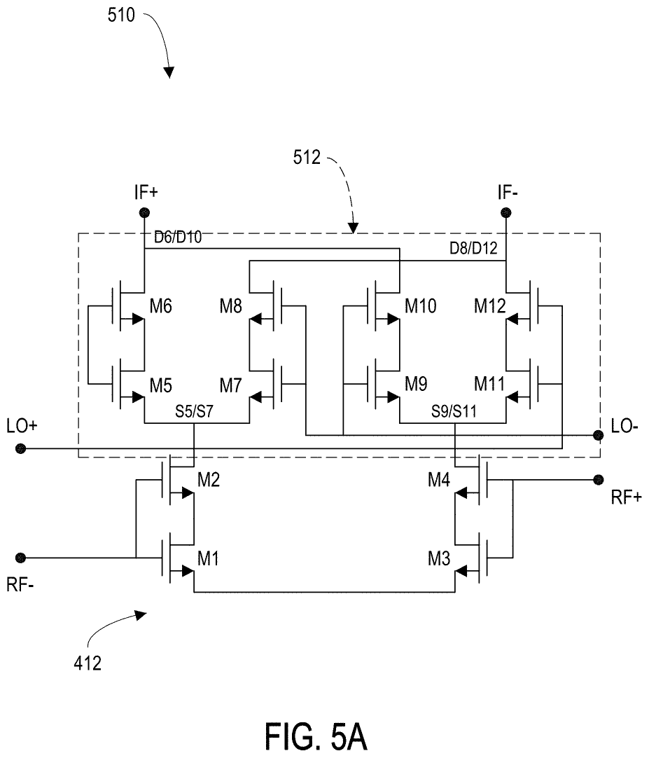

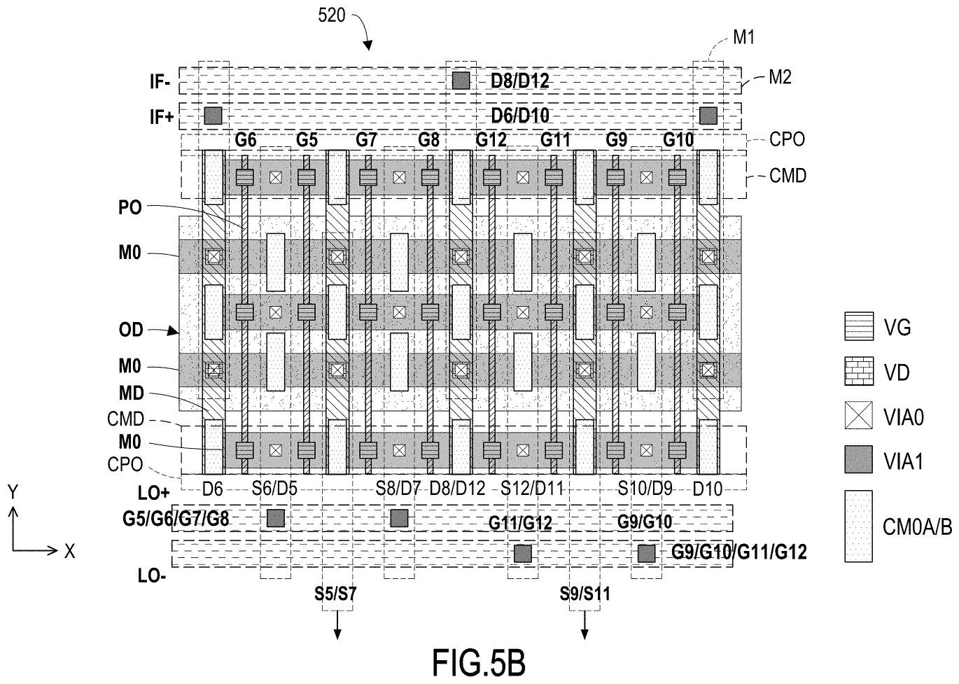

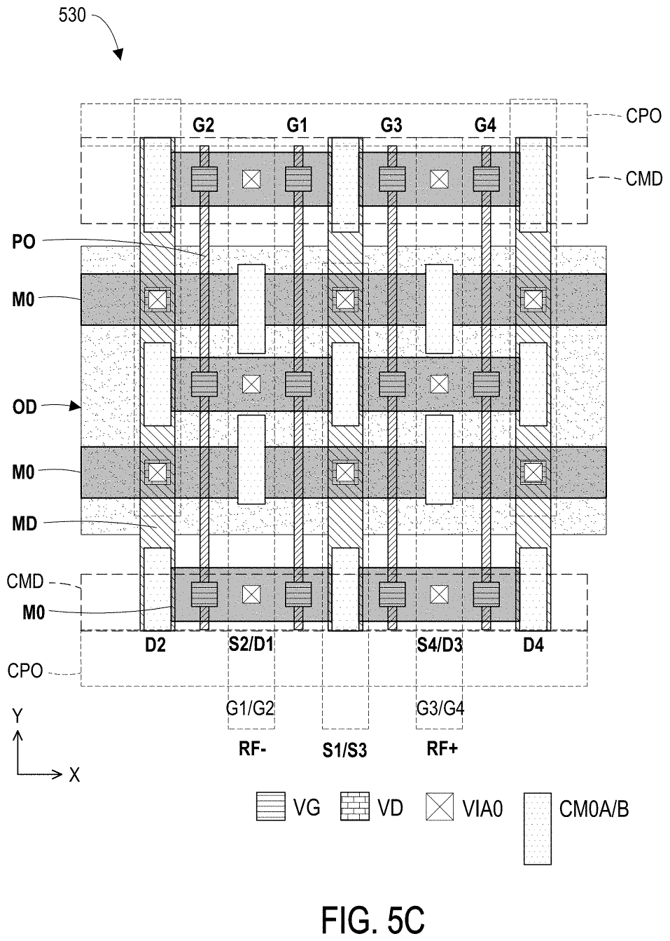

FIG. 5A is a circuit diagram of an RF mixer circuit 510 based on an octa gate circuit 512 in accordance with some embodiments. The RF mixer circuit 510 is configured to generate output signals IF based on low oscillation (LO) signals and RF signals. The RF mixer circuit 510 includes the octa gate circuit 512 and the quad gate circuit 412. The description of the quad gate circuit 412 previously described with respect to FIG. 4C applies for the RF nodes RF− and RF+. In the octa gate circuit 410 of this example, common drains D6 and D10 couple to first output node IF+, and common drains D8 and D12 couple to second output node IF−. Additionally, gates G5, G6, G11 and G12 couple to a first node LO+ and gates G7, G8, G9, and G10 couple to a second node LO−. Moreover, common sources S5 and S7 couple to the drain D2 of the quad gate circuit 412, and common sources S9 and S11 couple to the drain D4 of the quad gate circuit 412.

FIG. 5B illustrates a cell layout 520 showing MEOL layer connections for the octa gate circuit 512 of the RF mixer circuit 510 in accordance with some embodiments. FIG. 5C illustrates a cell layout 530 showing MEOL layer connections for the quad gate circuit 412 of the RF mixer circuit 510 in accordance with some embodiments. The cell layouts 520/530 are similar to that already described with respect to FIG. 4 and the description of such is thus omitted for brevity.

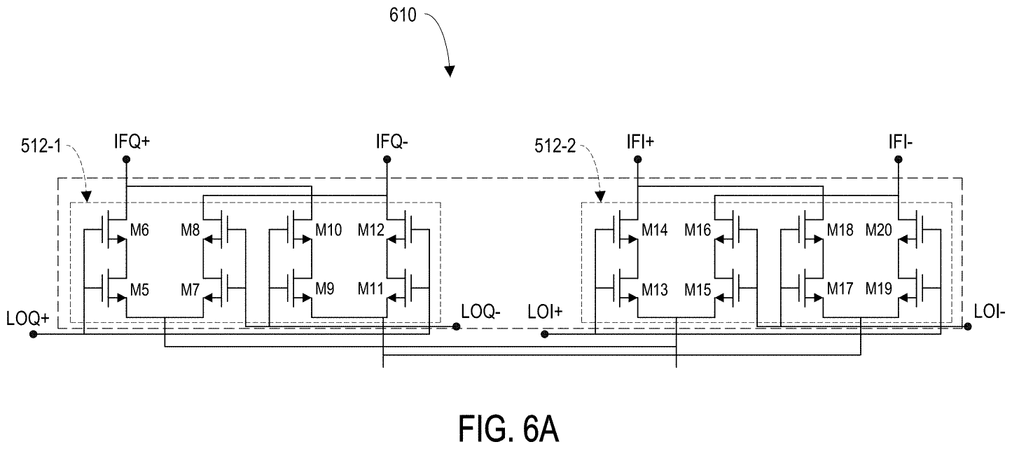

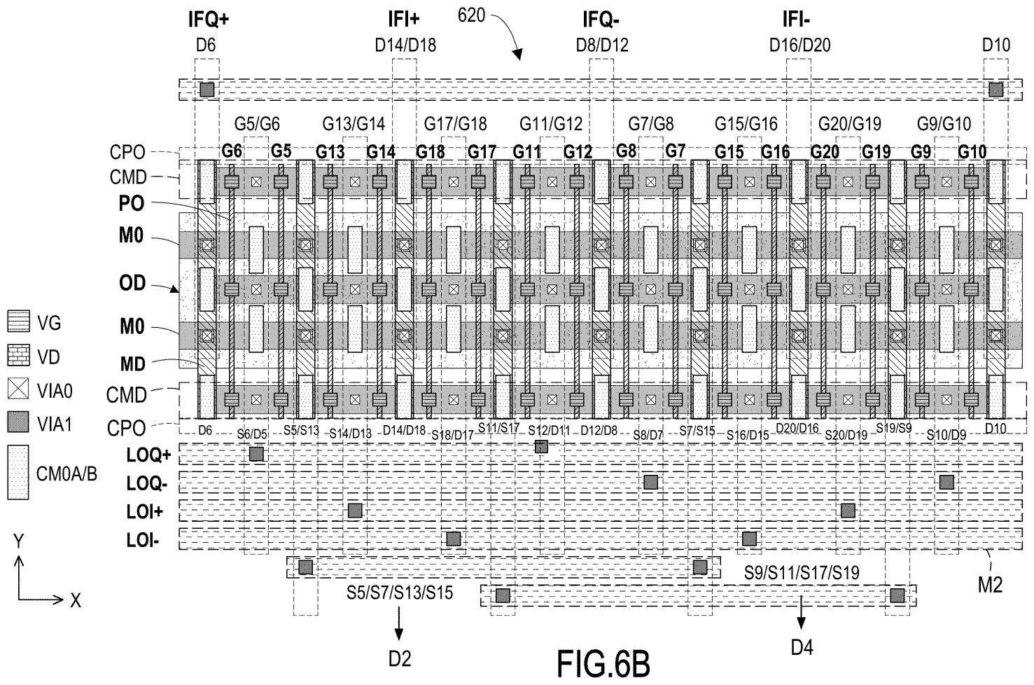

FIG. 6A is a circuit diagram of a hexadeca gate circuit 610 based on the octa gate circuit 512 in accordance with some embodiments. FIG. 6B illustrates a cell layout 620 showing MEOL layer connections for the hexadeca gate circuit 610 in accordance with some embodiments. In particular, a first octa gate circuit 512-1 and second octa gate circuit 512-2 are combined, or placed back-to-back together, to form a hexadeca gate. The first octa gate circuit 512-1 includes the eight transistors M5-M12 and connections described above with respect to FIG. 5A. The second octa gate circuit 512-2 is similarly configured with eight transistors M13-M20. In this example, the first octa gate circuit 512-1 includes output nodes IFQ+ and IFQ− and input nodes LOQ+ and LOQ−, and the second octa gate circuit 512-2 includes output nodes IFI+ and IFI− and input nodes LOI+ and LOI−. The connections and layout is similar to the other octa gates already described and further description of such is thus omitted for brevity.

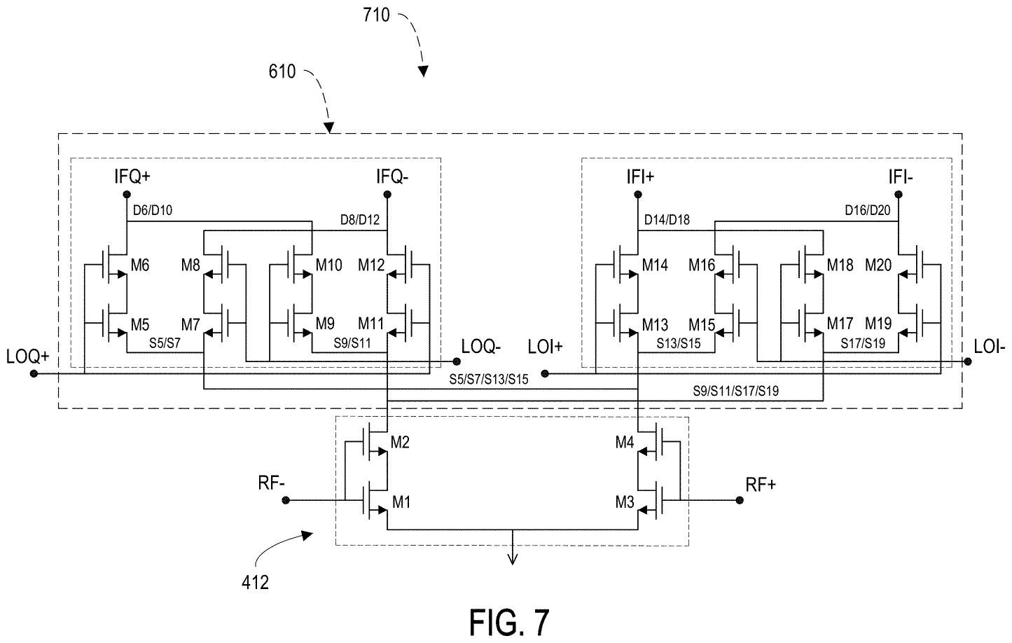

FIG. 7 is a circuit diagram of a Quadrature Gilbert cell circuit 710 based on the hexadeca gate circuit 610 in accordance with some embodiments. The Quadrature Gilbert cell circuit 710 is formed by the hexadeca gate circuit 610 coupled to the quad gate circuit 412. The description of the quad gate circuit 412 previously described with respect to FIGS. 4C and 5C applies and the description of such is thus omitted here for brevity. The drain D2 of the quad gate circuit 412 couples to the common sources S9, S11, S17, and S19. Similarly, the drain D4 of the quad gate circuit 412 couples to the common sources S5, S7, S13, and S15. The description of the hexadeca gate circuit 610 described above with respect to FIG. 6A applies and the description of such is thus omitted here for brevity.

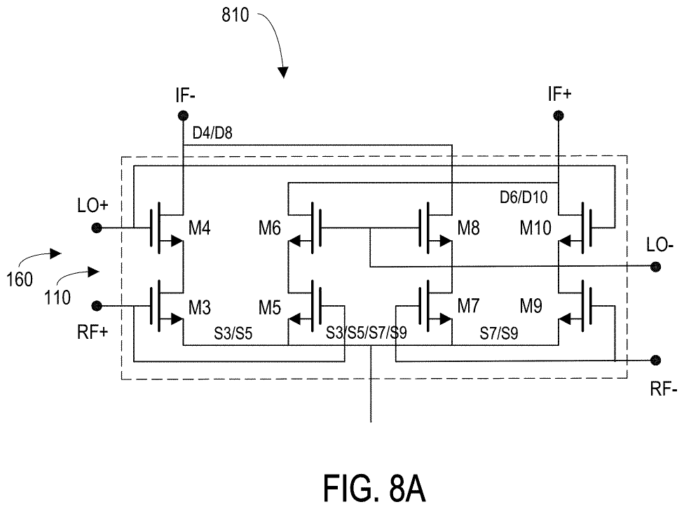

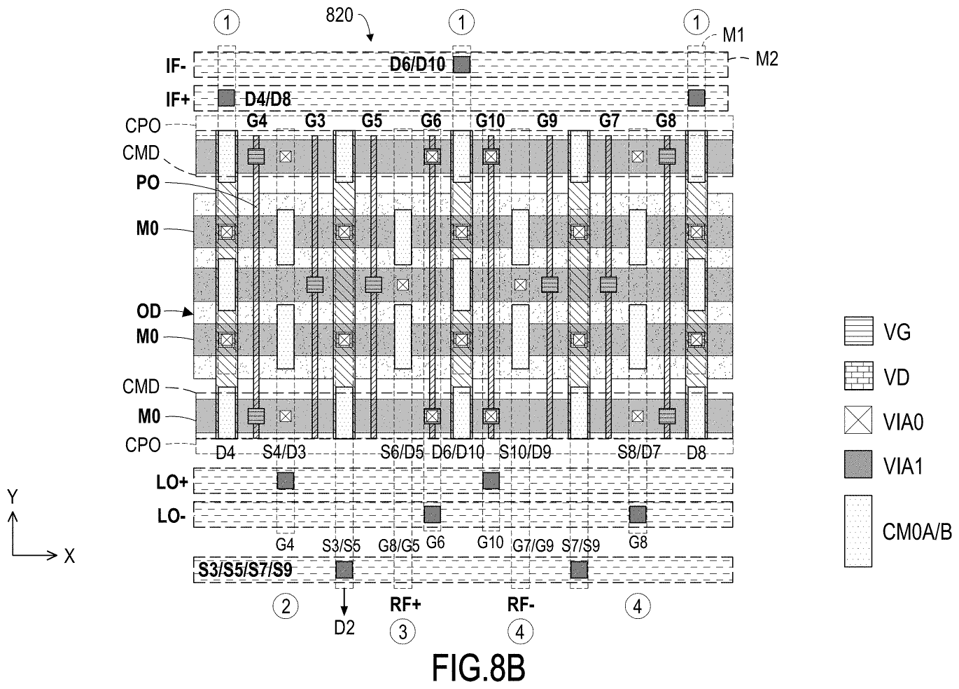

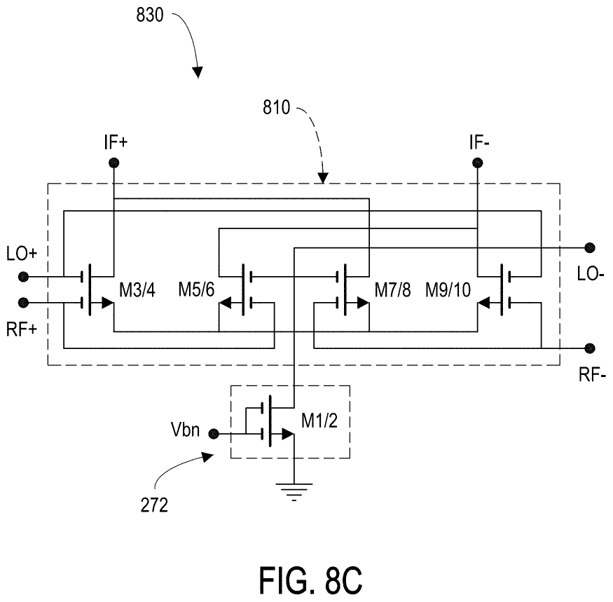

FIG. 8A is a circuit diagram of an octa gate circuit 810 including the cascoded transistor configuration 160 of the first type of dual-gate design 110 in accordance with some embodiments. In this example, the octa gate circuit 810 includes eight transistors M3-M10. Transistors M3 and M4 are in the cascoded transistor configuration 160 and coupled input nodes RF+ and LO+, respectively. Transistor pairs M5/M6, M7/M8, and M9/M10 are also in the cascoded transistor configuration 160. Gates G7 and G9 are coupled to input node RF−, and gates G6 and G8 are coupled to input node LO−. Common drains D6 and D10 couple to a first output IF+, and common drains D4 and D8 couple to a second output IF−. Sources S3, S5, S7, and S9 are coupled together.

FIG. 8B illustrates a cell layout 820 showing MEOL layer connections for the octa gate circuit 810 in accordance with some embodiments. In particular, the eight transistors M3-M10 are formed across the active region OD of the cell. Common drains D6 and D10 are disposed at center and drains D4 and D8 are disposed at outer sides and connected by the third metallization layer M2. Gates G10 and G6 are disposed outward from center at right and left sides, respectively. Gates G9 and G5 are disposed further outward therefrom at right and left sides, respectively. Gates G7 and G3 are disposed further outward therefrom at right and left sides, respectively. Gates G8 and G4 are disposed at outer right and left sides of the cell, respectively.

Sources S3, S5, S7, and S9 are common and connected to the third metallization layer M2 with a VIA1 disposed between gates G3 and G5 and a VIA1 disposed between gates G7 and G9. Gates G3 and G5 are common by a connection to the second metallization layer M1, and both sides of gate G4 are connected to the second metallization layer M1. Gates G7, G9, and G8 respectively mirror the configuration of gates G3, G5, and G4.

FIG. 8C is a circuit diagram of an RF mixer circuit 830 based on the octa gate circuit 810 in accordance with some embodiments. The RF mixer circuit 830 includes the octa gate circuit 810 coupled to a dual-gate stacked cell 272 to form a double balanced RF mixer. As earlier described, RF and LO input signals are connected to the first and second gates of a cascoded cell, respectively. The dual-gate stacked cell 272 is connected to the common sources S3, S5, S7, and S9 of the octa gate circuit 810. The connections and layout of the dual-gate stacked cell 272 are described with respect to FIGS. 2C-2D.

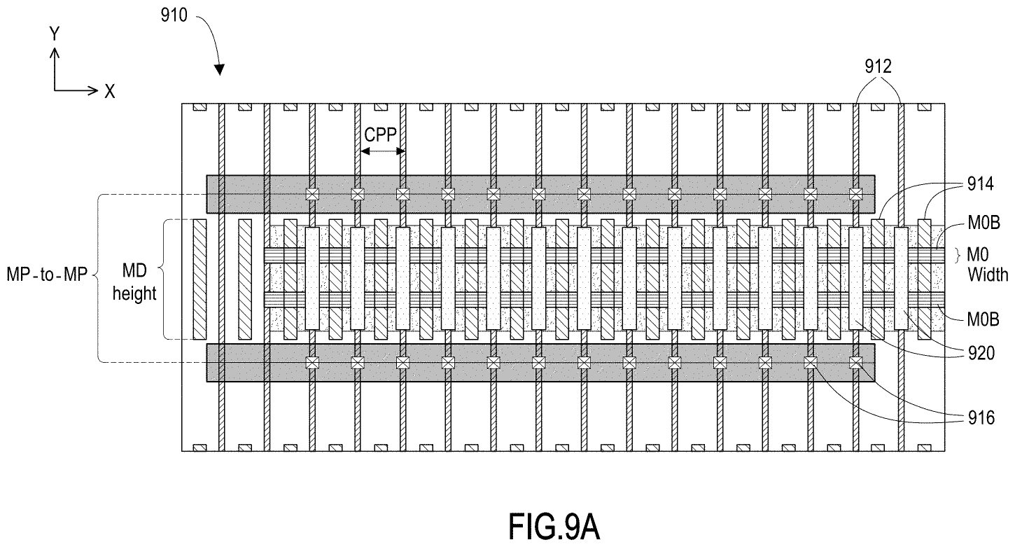

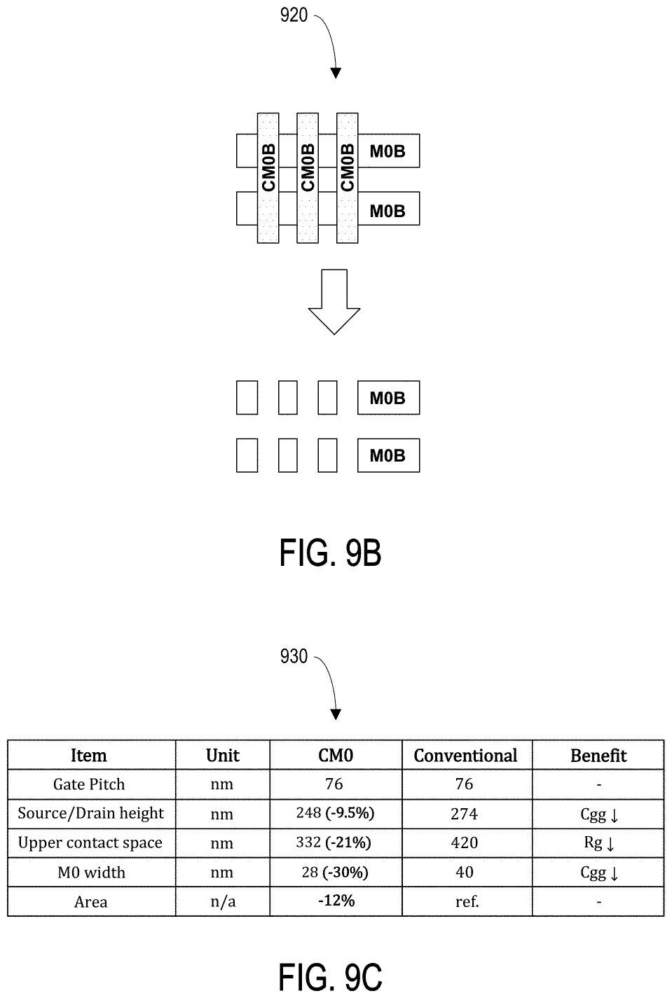

FIG. 9A illustrates a cell layout 910 with a cut first metallization layer M0 in accordance with some embodiments. The cell layout 910 includes gates 912, MD layer tracks 914, connection vias 916, and a first metallization layer M0. In particular, the first metallization layer M0 may include one or more metal tracks MOB extending over the gates 912 in an orthogonal direction (e.g., X-direction). Additionally, cell layout 910 is enhanced with cut metallization tracks CM0B to reduce parasitic capacitance and gate resistance for the cell. The cut metallization tracks CM0B extend across the metal tracks M0B in a Y-direction in alignment over respective gates 912. That is, M0B may comprise a second patterning of the first metallization layer, and CM0B may comprise the cut of M0B.

FIG. 9B is a schematic diagram 920 of the first metallization layer M0 with perpendicular cut-metal layer in accordance with some embodiments. FIG. 9C is a table 930 summarizing characteristics of the cell layout 910 having the cut first metallization layer M0 in accordance with some embodiments. As shown in FIG. 9B, the first metallization layer M0 is segmented by the cut metallization tracks CM0B. Referring now to the table 930 of FIG. 9C in conjunction with the a cell layout 910 of FIG. 9A, the cut first metallization layer M0 enables area reduction including a reduced MD height to decrease gate capacitance C_{gg}, a reduced MP-to-MP space to decrease gate resistance R_{g}, and a reduced M0 width which also decreases gate capacitance C_{gg}. These characteristics improve the RF performance (e.g., cut-off frequency f_{T} and maximum oscillation frequency fₘₐₓ) of an RF circuit.

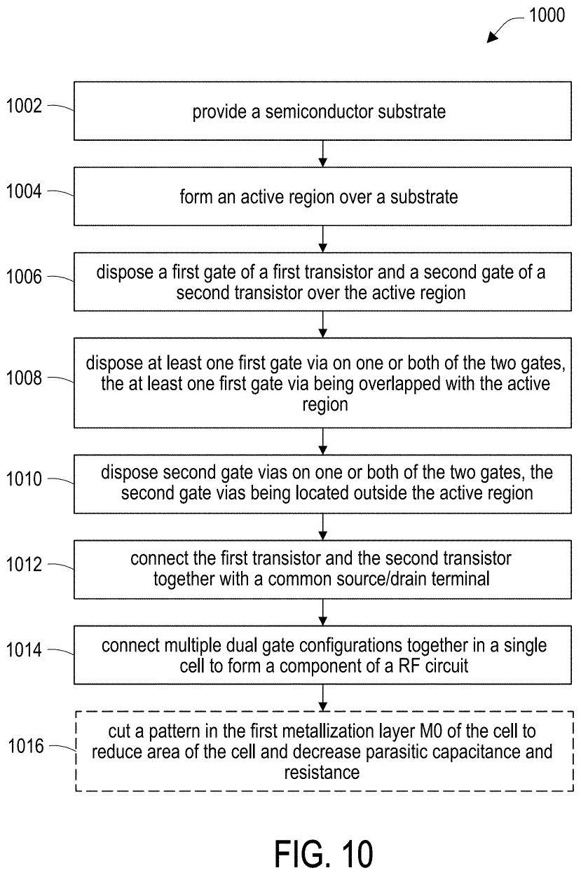

FIG. 10 illustrates an example method 1000 of forming a cell in accordance with some embodiments. Although the method is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At step 1002, a semiconductor substrate is provided. At step 1004, an active region OD of a cell is formed over the substrate. At step 1006, a first gate (e.g., G1) of a first transistor and a second gate (e.g., G2) of a second transistor are disposed over the active region OD of the cell. At step 1008, at least one first gate via (e.g., VG 150-1) is disposed on one or both of the two gates, the at least one first gate via being overlapped with the active region OD. At step 1010, second gate vias (e.g., VGs 150-2 and/or 150-3) are disposed on one or both of the two gates, the second gate vias being located outside the active region OD. At step 1012, the first transistor and the second transistor are connected together with a common source/drain terminal. Accordingly, method 1000 may be used to form a cell according to either the first type of dual-gate design 110 or the second type of dual-gate design 210. Optionally, at step 1014, multiple dual-gate configurations may be connected together in a single cell to form a component of a RF circuit. Additionally, at optional step 1016, a pattern may be cut in the first metallization layer M0 of the cell to reduce the area of the cell and decrease parasitic capacitance and resistance.

Accordingly, the various embodiments disclosed herein provide an integrated circuit. The integrated circuit includes a dual-gate cell forming two transistors connected with each other via a common source/drain terminal. The dual-gate cell includes an active region, two gate lines extending across the active region, at least one first gate via disposed on one or both of the two gate lines and overlapped with the active region, and second gate vias disposed on one or both of the two gate lines and located outside the active region.

A further embodiment includes a cell for connecting transistors of a circuit. The cell includes an active region, and multiple pairs of transistors in the circuit, each pair of transistors having a connected source/drain terminal between the pair, and the transistors having respective gates extending over the active region. The cell also includes at least one first gate via disposed on one or both gates of each pair of transistors and overlapped with the active region, and second gate vias disposed on one or both of gates of each pair of transistors and located outside the active region.

In accordance with further disclosed embodiments, a method of forming a cell is disclosed. The method includes forming an active region of the cell over a substrate, disposing a first gate of the first transistor and a second gate of the second transistor over an active region of the cell, disposing at least one first gate via on one or both of the two gates, the at least one first gate via being overlapped with the active region, and disposing second gate vias on one or both of the two gates, the second gate vias being located outside the active region.

This disclosure outlines various embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit, comprising:
a dual-gate cell forming two transistors connected with each other via a common source/drain terminal, wherein the dual-gate cell comprises:
an active region;
two gate lines extending across the active region;
at least one first gate via disposed on one or both of the two gate lines and overlapped with the active region; and
second gate vias disposed on one or both of the two gate lines and located outside the active region.

2. The integrated circuit of claim 1, wherein the two gate lines include:
a first gate line having a single gate via disposed thereon, the single via overlapped with the active region; and
a second gate line having two gate vias disposed thereon, the two gate vias located outside the active region.

3. The integrated circuit of claim 2, wherein the dual-gate cell connects the two transistors in a cascoded configuration for a low noise amplifier.

4. The integrated circuit of claim 1, wherein the two gate lines include:
a first gate line having three gate vias disposed thereon, wherein one of the three gate vias is overlapped with the active region and two of the three gate vias are located outside the active region; and
a second gate line having three gate vias disposed thereon, wherein one of the three gate vias is overlapped with the active region and two of the three gate vias are located outside the active region.

5. The integrated circuit of claim 4, wherein the dual-gate cell connects the two transistors in a stacked gate configuration for a voltage-controlled oscillator.

6. The integrated circuit of claim 4, wherein the dual-gate cell connects the two transistors in a stacked gate configuration for a mixer.

7. The integrated circuit of claim 4, wherein the two transistors of the dual-gate cell couple to a quad gate stacked cell to form a voltage-controlled oscillator.

8. The integrated circuit of claim 1, wherein the at least one gate via and the second gate vias connect the gate lines to a first metallization layer.

9. The integrated circuit of claim 8, wherein the first metallization layer is cut into segments by tracks extending orthogonal to the first metallization layer.

10. A cell for connecting transistors of a circuit, the cell comprising:
an active region;
multiple pairs of transistors in the circuit, each pair of transistors having a connected source/drain terminal between the pair, and the transistors having respective gates extending over the active region;
at least one first gate via disposed on one or both gates of each pair of transistors and overlapped with the active region; and
second gate vias disposed on one or both of gates of each pair of transistors and located outside the active region.

11. The cell of claim 10, wherein the gates of each pair of transistors include:
a first gate having a single gate via disposed thereon, the single via overlapped with the active region; and
a second gate having two gate vias disposed thereon, the two gate vias located outside the active region.

12. The cell of claim 11, wherein the cell connects each pair of the transistors in a cascoded configuration to form a low noise amplifier.

13. The cell of claim 10, wherein the gates of each pair of transistors include:
a first gate having three gate vias disposed thereon, wherein one of the three gate vias is overlapped with the active region and two of the three gate vias are located outside the active region; and
a second gate having three gate vias disposed thereon, wherein one of the three gate vias is overlapped with the active region and two of the three gate vias are located outside the active region.

14. The cell of claim 11, wherein the cell connects each pair of the transistors in a stacked gate configuration to form a mixer.

15. The cell of claim 11, wherein the cell connects each pair of the transistors in a stacked gate configuration to form a voltage-controlled oscillator.

16. The cell of claim 11, wherein the at least one gate via and the second gate vias connect the gate lines to a first metallization layer.

17. A method of forming a cell, the method comprising:
forming an active region of the cell over a substrate;
disposing a first gate of a first transistor and a second gate of a second transistor over the active region;
disposing at least one first gate via on one or both of the two gates, the at least one first gate via being overlapped with the active region; and
disposing second gate vias on one or both of the two gates, the second gate vias being located outside the active region.

18. The method of claim 17, further comprising:
cutting a pattern in a first metallization layer of the cell to reduce an area of the cell.

19. The method of claim 17, wherein the first transistor and the second transistor are coupled in a dual-gate configuration with a common source/drain terminal.

20. The method of claim 19, further comprising:
connecting multiple ones of the dual-gate configuration together in the cell to form a component of a RF circuit.
